(19) United States
(12) Patent Application Publication
(10) Pub. No.: US 2012/0205773 A1
(43) Pub. Date: Aug. 16, 2012

(54) SCHOTTKY DIODE WITH LOWERED FORWARD VOLTAGE DROP

(75) Inventors: Chiun-Yen TUNG, Kaohsiung City (TW); Po-Chang HUANG, Kaohsiung City (TW); Wei-Sheng CHAO, Kaohsiung City (TW); Kun-Hsien CHEN, Kaohsiung City (TW)

(73) Assignee: PYNMAX TECHNOLOGY CO., LTD., Dongguan (CN)

(21) Appl. No.: 13/186,495

(22) Filed: Jul. 20, 2011

(30) Foreign Application Priority Data
Feb. 11, 2011 (TW) 100202612

(51) Int. Cl. H01L 29/872

(52) U.S. Cl. 257/475; 257/E29.338

(57) ABSTRACT

A Schottky diode with a lowered forward voltage drop has an N− type doped drift layer formed on an N+ type doped layer. The N− type doped drift layer has a surface formed with a protection ring inside which is a P-type doped layer. The surface of the N− type doped drift layer is further formed with an oxide layer and a metal layer. The contact region between the metal layer and the N− type doped drift layer within the P-type doped layer forms a Schottky barrier. An upward extending N type doped layer is formed on the N+ type doped layer and under the Schottky barrier to reduce the thickness of the N− type doped drift layer under the Schottky barrier. This lowers the forward voltage drop of the Schottky diode.

### BACKGROUND OF THE INVENTION

1. Field of the Invention

The invention relates to a Schottky diode and, in particular, to a Schottky diode with a lowered forward voltage drop.

2. Description of Related Art

With reference to FIG. 6, a Schottky diode has an N− type doped drift layer 81 formed on an N+ type doped layer 80. The N− type doped drift layer 81 is formed with a protection ring 82 inside which is a P-type doped layer. The surface of the N− type doped drift layer 81 is further formed with an oxide layer 83 and a metal layer 84. The contact region between the metal layer 84 and the N− type doped drift layer 81 within the P-type doped layer forms a Schottky barrier 85. The bottom surface of the N+ type doped layer 80 is formed with a metal layer as a bottom electrode 86.

In the above-mentioned structure, free electrons in the N− type doped drift layer 81 have a lower energy level than those in the metal layer 84. Without a bias, the electrons in the N− type doped drift layer 81 cannot move to the metal layer 84. When a forward bias is imposed, the free electrons in the N− type doped drift layer 81 have sufficient energy to move to the metal layer 84, thereby producing an electric current. Since the metal layer 84 does not have minor carriers, electric charges cannot be stored. Therefore, the reverse restoring time is very short. According to the above description, the Schottky diode uses the junction between the metal and the semiconductor as the Schottky barrier for current rectification. It is different from the PN junction formed by semiconductor/semiconductor junction in normal diodes. The characteristics of the Schottky barrier render a lower forward voltage drop for the Schottky diode. The voltage drop of normal PN junction diodes is 0.7-1.7 volts. The voltage drop of the Schottky diode is 0.15-0.45 volts. The characteristics of the Schottky barrier also increase the switching speed.

With reference to FIG. 7, the characteristic curve of the Schottky diode shows the relation between the forward voltage V and the current I and relationship between the reverse breakdown voltage and the current I. The characteristic curve indicates that as the current I becomes larger, the forward voltage V also becomes higher. The rise in the forward voltage definitely affects the characteristics and applications of the Schottky diode. According to experimental results, the forward voltage of the Schottky diode is proportional to the thickness D of the N− type doped drift layer 81 under the Schottky barrier 85. As the thickness D of the N− type doped drift layer 81 becomes larger, the forward voltage also becomes higher. On the other hand, as the thickness D of the N− type doped drift layer 81 becomes thinner, the forward voltage also becomes lower.

### SUMMARY OF THE INVENTION

An objective of the invention is to provide a Schottky diode with a lowered forward voltage drop. A change in the structure of the Schottky diode according to the invention can lower the forward voltage drop thereof without changing its reverse breakdown voltage.

To achieve the above-mentioned objective, the Schottky diode includes: an N+ type doped layer, an N type doped layer, an N− type doped drift layer, an oxide layer, and a metal layer. The N type doped layer is locally formed on the N+ type doped layer and has an ion concentration being higher than that of the N+ type doped layer. The N− type doped drift layer is formed on the N+ type doped layer and the N type doped layer. The N− type doped drift layer has a surface formed with a concave protection ring, inside which is a P-type doped layer. The oxide layer is formed on the N− type doped drift layer. The metal layer is formed on the oxide layer and the N− type doped drift layer. The contact region between the metal layer and the oxide layer within the N− type doped drift layer forms a Schottky barrier. The Schottky barrier is correspondingly above the N type doped layer.

Since the N+ type doped layer is formed with an N type doped layer under the Schottky barrier, the thickness of the N− type doped drift layer between the N type doped layer and the Schottky barrier becomes thinner, thereby reducing the forward voltage drop of the Schottky diode.

### BRIEF DESCRIPTION OF THE DRAWINGS

FIG. 1 is a schematic view of a first embodiment of the Schottky diode in accordance with the present invention;

FIG. 2 is another schematic view of the first embodiment of the Schottky diode;

FIG. 3 is yet another schematic view of the first embodiment of the Schottky diode;

FIG. 4 shows a characteristic curve of the Schottky diode of the invention;

FIG. 5 is a schematic view of a conventional Schottky diode;

FIG. 6 is another schematic view of the conventional Schottky diode; and

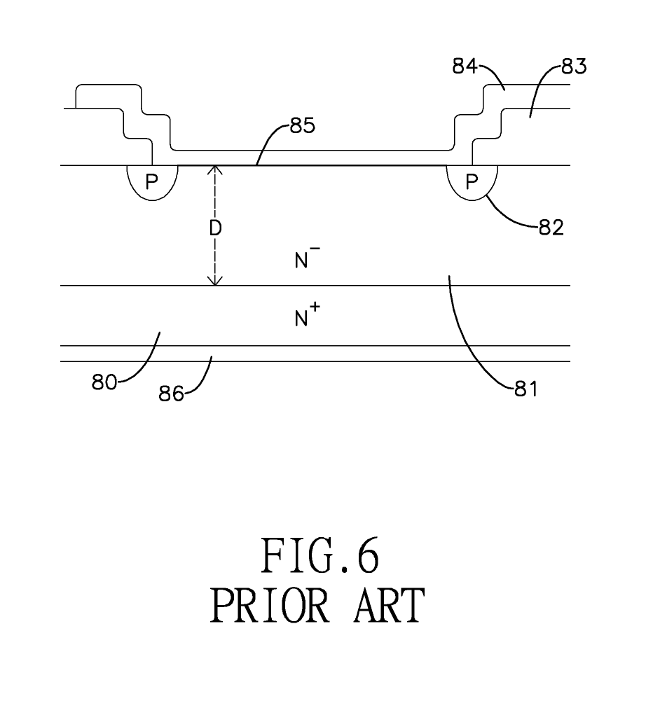

FIG. 7 shows a characteristic curve of the conventional Schottky diode.

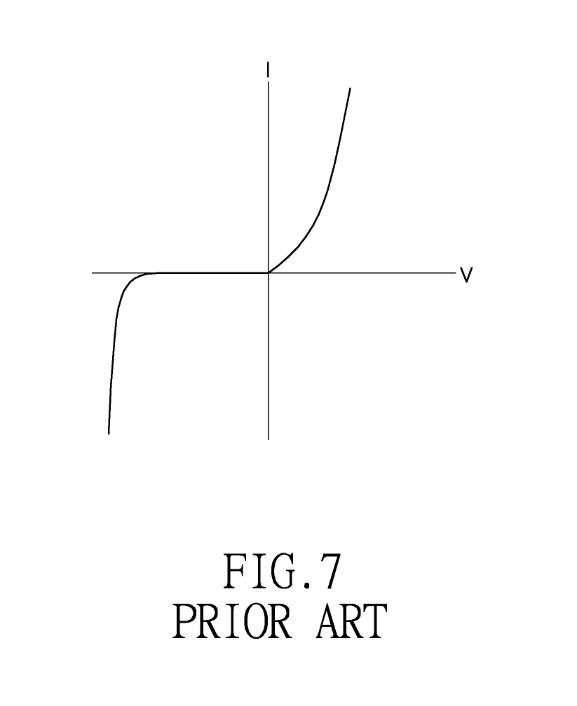

### DETAILED DESCRIPTION OF THE PREFERRED EMBODIMENT

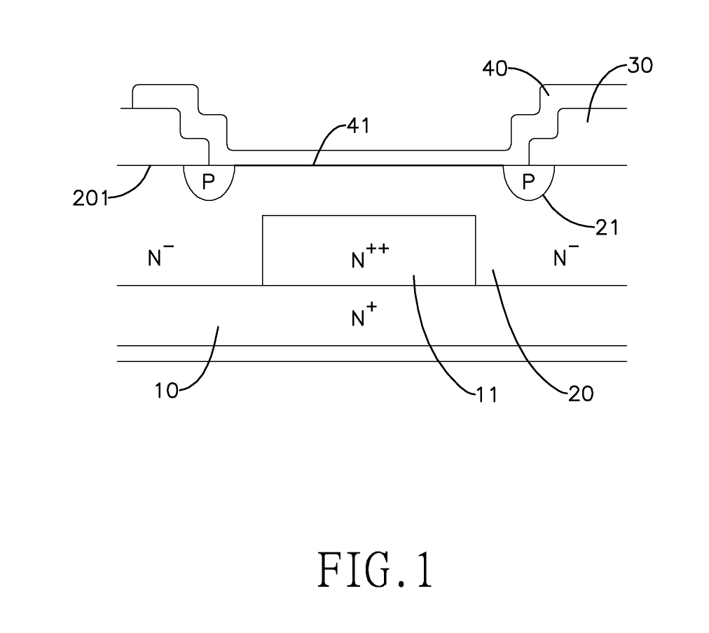

With reference to FIG. 1, a first embodiment of the invention comprises an N− type doped drift layer 20 formed on an N+ type doped layer 10. The N− type doped drift layer 20 has a surface 201 formed with an embedded protection ring 21 inside which is a P-type doped layer. The surface 201 of the N− type doped drift layer 20 is further formed with an oxide layer 30, which partly covers and contacts the P-type doped layer in the protection ring 21. Moreover, a metal layer 40 is formed on the N− type doped drift layer 20 and the oxide layer 30. The contact region between the metal layer 40 and the N− type doped drift layer 20 within the P-type doped layer forms a Schottky barrier 41.

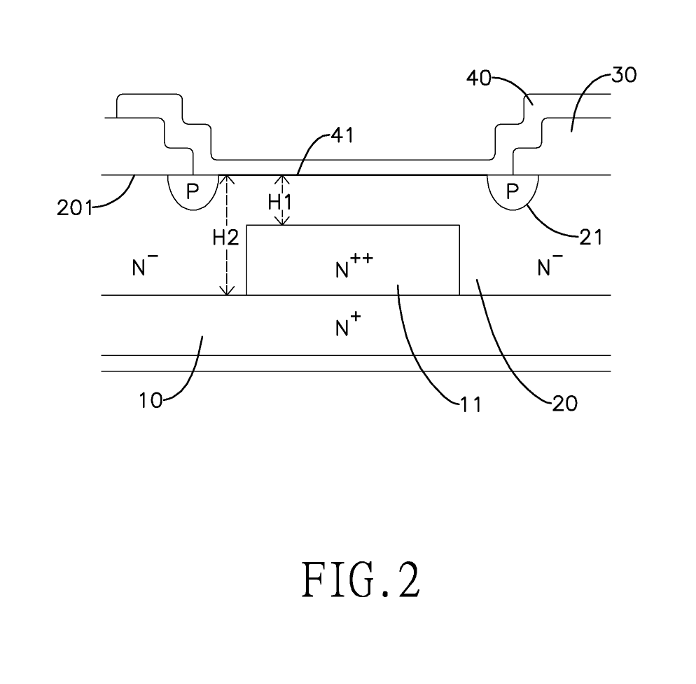

To reduce the thickness of the N− type doped drift layer 20 under the Schottky barrier 41, an N type doped layer 11 is locally formed on the N+ type doped layer 10. Afterwards, an N− type doped drift layer 20 is formed on the N+ type doped layer 10 and the N type doped layer 11. Since the N type doped layer 11 is higher than the N+ type doped layer 10 while the N− type doped drift layer 20 has a surface of same horizontal height 201, as shown in FIG. 2, the thickness H1 of the N− type doped drift layer 20 above the N type doped layer 11 is thus smaller than the thickness H2 of the N− type doped drift layer 20 above the N+ type doped layer 10. In addition to reducing the thickness of the N− type doped drift layer 20, locally forming an N type doped layer 11 with a higher ion concentration than the N− type doped drift layer 20 has the advantage of providing major carriers due to the high ion concentration.

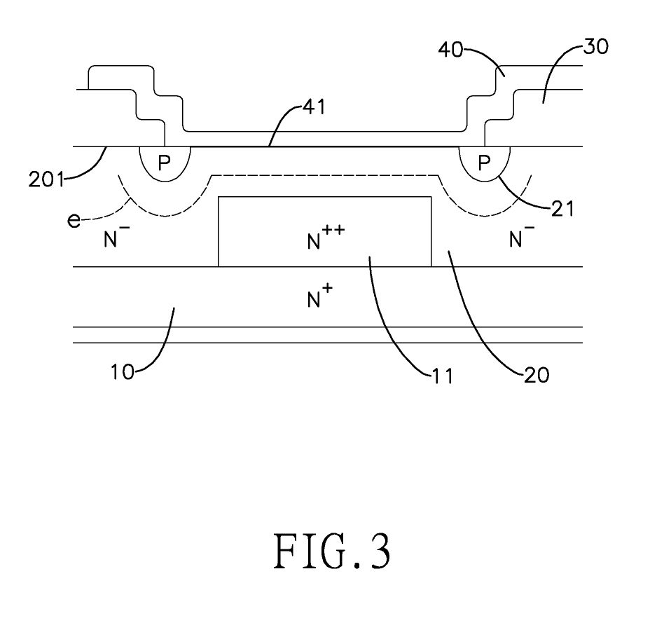

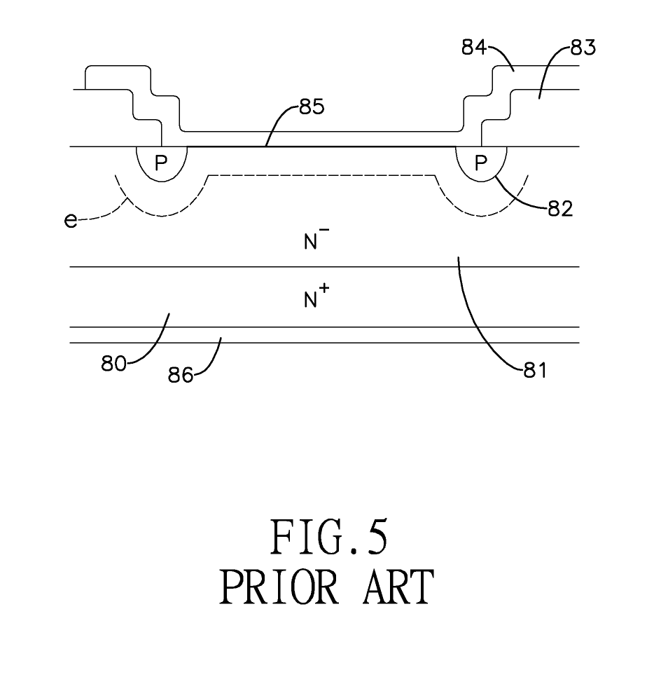

Although the invention reduces the thickness of the N− type doped drift layer 20 under the Schottky barrier 41 to lower the forward voltage drop, it still ensures that the reverse breakdown voltage is not affected. FIG. 5 is a schematic view of the structure of a conventional Schottky diode. During the reverse restoring, the N− type doped drift layer 81 forms an electric field e under and in the profile similar to the P-type doped layer and the Schottky barrier 85. The invention forms the N type doped layer 11 on the N+ type doped layer 10 to reduce the thickness of the N− type doped drift layer 20 above. As long as the N type doped layer 11 does not exceed the edges of the electric field e (as shown in FIG. 3), the reverse breakdown voltage is guaranteed not to change.

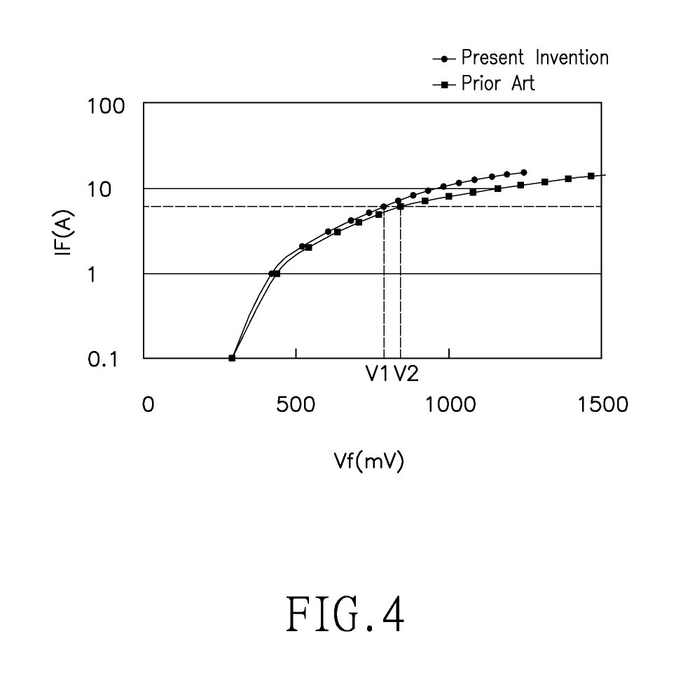

FIG. 4 shows different characteristic curves of the invention and the Schottky diode in the prior art obtained from experiments. The characteristic curves show that under the same electric current, the forward voltage drop V1 of the invention is smaller than the forward voltage drop V2 of the Schottky diode in the prior art.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A Schottky diode with a lowered forward voltage drop comprising:
an N+ type doped layer;
an N type doped layer locally formed on the N+ type doped layer and having an ion concentration smaller than that of the N+ type doped layer;
an N− type doped drift layer formed on the N+ type doped layer and the N type doped layer, having an ion concentration smaller than that of the N type doped layer and having a surface formed with a protection ring inside which is a P-type doped layer;
an oxide layer formed on the N− type doped drift layer; and
a metal layer formed on the oxide layer and the N− type doped drift layer, wherein a contact region between the metal layer and the N− type doped drift layer within the P-type doped layer forms a Schottky barrier.

2. The Schottky diode as claimed in claim 1, wherein the N type doped layer is correspondingly under the Schottky barrier.

3. The Schottky diode as claimed in claim 1, wherein the N type doped layer does not exceed edges of an electric field produced during reverse restoring of the N− type doped drift layer.
